(19) United States
(12) Patent Application Publication
(10) Pub. No.: US 2024/0407242 A1
(43) Pub. Date: Dec. 5, 2024

(54) DISPLAY DEVICE AND METHOD FOR MANUFACTURING DISPLAY DEVICE

(71) Applicant: Sharp Display Technology Corporation, Kameyama City, Mie (JP)

(72) Inventor: Takayuki SHUTO, Kameyama City, Mie (JP)

(21) Appl. No.: 18/698,344

(22) PCT Filed: Dec. 29, 2021
(86) PCT No.: PCT/JP2021/049013

§ 371 Date: Apr. 3, 2024

(51) Int. Cl. H10K 59/88; H10K 50/15; H10K 50/16; H10K 50/17; H10K 59/00; H10K 59/12; H10K 59/35

(52) U.S. Cl. CPC H10K 59/88; H10K 59/1201; H10K 59/35; H10K 59/771; H10K 50/15; H10K 50/16; H10K 50/17; H10K 50/171

(57) ABSTRACT

A display device includes a substrate; a display region located on the substrate and provided with a plurality of pixels each including a plurality of subpixels; a non-display region located on the substrate, including a plurality of dummy subpixels provided along an end portion of the display region, and continued from the display region; a plurality of lower electrodes; a charge transfer layer; and an upper electrode. The plurality of subpixels provided in the display region each include a light-emitting element including the lower electrode, the charge transfer layer, a light-emitting layer, and the upper electrode in that order from the substrate side, and the plurality of dummy subpixels provided in the non-display region each include a non-emitting charge transfer element including the lower electrode, the charge transfer layer, and the upper electrode in that order from the substrate side.

### TECHNICAL FIELD

The disclosure relates to a display device and a method for manufacturing the display device.

### BACKGROUND ART

In recent years, various display devices including light-emitting elements have been developed. Particularly, a display device including an organic light emitting diode (OLED) or a quantum dot light emitting diode (QLED) has drawn a great deal of attention because advantages such as lower power consumption, smaller thickness, and higher picture quality can be achieved.

In the field of these display devices, a charge transfer layer (at least one of a hole injection layer and a hole transport layer, or at least one of an electron injection layer and an electron transport layer) provided between a lower electrode and a light-emitting layer included in a light-emitting element is often formed over the entire surface of a display region.

PTL 1 describes a display device in which each of a hole injection layer and a hole transport layer is formed over the entire surface of a display region as a charge transfer layer provided between a lower electrode and a light-emitting layer included in an OLED.

### CITATION LIST

### Patent Literature

PTL 1: JP 2014-164829 A

### SUMMARY

### Technical Problem

In a case where at least one of a hole injection layer and a hole transport layer is formed over the entire surface of a display region as a charge transfer layer provided between a lower electrode and a light-emitting layer included in a light-emitting element as in the display device described in PTL 1, there is a problem that a bright line appears in an end portion area of the display region.

Such a problem also arises in a case where at least one of an electron injection layer and an electron transport layer is formed over the entire surface of the display region as a charge transfer layer provided between the lower electrode and the light-emitting layer included in the light-emitting element, and a bright line appears in the end portion area of the display region.

An aspect of the disclosure has been contrived in light of the above-mentioned problem. An object thereof is to provide a display device in which, even when a charge transfer layer provided between a lower electrode and a light-emitting layer included in a light-emitting element is formed over the entire surface of a display region, a situation where a light-emitting element provided in an end portion area of the display region emits light with luminance higher than the intended luminance and a bright line appears is suppressed, and to provide a method for manufacturing the above display device.

### Solution to Problem

In order to solve the above problem, a display device according to the disclosure includes:
a substrate;
a display region located on the substrate and provided with a plurality of pixels each including a plurality of subpixels;
a non-display region located on the substrate, including a plurality of dummy subpixels provided along an end portion of the display region, and continued from the display region;
a plurality of lower electrodes provided in each of the display region and the non-display region;
a charge transfer layer which is one layer provided in the display region and the non-display region; and
an upper electrode provided in the display region and the non-display region, wherein
the plurality of subpixels provided in the display region each include a light-emitting element including the lower electrode, the charge transfer layer, a light-emitting layer, and the upper electrode in that order from the substrate side, and
the plurality of dummy subpixels provided in the non-display region each include a non-emitting charge transfer element including the lower electrode, the charge transfer layer, and the upper electrode in that order from the substrate side.

In order to solve the above-mentioned problem, a method for manufacturing a display device according to the disclosure includes:
forming a plurality of lower electrodes in each of a display region located on a substrate and a non-display region located on the substrate and continued from the display region;
forming an upper electrode in the display region and the non-display region after the forming a plurality of lower electrodes;
forming a light-emitting layer only in the display region between the forming a plurality of lower electrodes and the forming an upper electrode; and
forming a charge transfer layer made of one layer in the display region and the non-display region between the forming a plurality of lower electrodes and the forming a light-emitting layer.

### Advantageous Effects of Disclosure

An aspect of the disclosure has been contrived in light of the above-mentioned problem. The disclosure can provide a display device in which, even when a charge transfer layer provided between a lower electrode and a light-emitting layer included in a light-emitting element is formed over the entire surface of a display region, a situation where a light-emitting element provided in an end portion area of the display region emits light with luminance higher than the intended luminance and a bright line appears is suppressed, and can also provide a method for manufacturing the above display device.

### BRIEF DESCRIPTION OF DRAWINGS

FIG. 1 is a plan view illustrating a schematic configuration of a display device according to a first embodiment.

FIG. 2 is a cross-sectional view illustrating a schematic configuration of a substrate provided in the display device according to the first embodiment illustrated in FIG. 1.

FIG. 3 is a cross-sectional view illustrating a schematic configuration of a light-emitting element provided in a display region and a non-emitting charge transfer element provided in a non-display region of the display device according to the first embodiment.

FIG. 4 is a diagram illustrating a circuit near a boundary between a display region and a non-display region of the display device according to the first embodiment illustrated in FIG. 3.

FIG. 5 is a cross-sectional view illustrating a schematic configuration of a display device according to a comparative example in which a light-emitting element provided in an end portion area of a display region emits light with luminance higher than the intended luminance and a bright line appears.

FIG. 6 is a circuit diagram for explaining a reason why a bright line appears in the end portion area of the display region of the display device according to the comparative example illustrated in FIG. 5.

FIG. 7 is a cross-sectional view illustrating a schematic configuration of a light-emitting element provided in a display region and a non-emitting charge transfer element provided in a non-display region of a display device according to a second embodiment.

FIG. 8 is a diagram illustrating a circuit near a boundary between a display region and a non-display region of the display device according to the second embodiment illustrated in FIG. 7.

FIG. 9 is a cross-sectional view illustrating a schematic configuration of a display device according to another comparative example in which a light-emitting element provided in an end portion area of a display region emits light with luminance higher than the intended luminance and a bright line appears.

FIG. 10 is a circuit diagram for explaining a reason why a bright line appears in the end portion area of the display region of the display device according to the another comparative example illustrated in FIG. 9.

FIG. 11 is a plan view illustrating a schematic configuration of a display device according to a third embodiment.

### DESCRIPTION OF EMBODIMENTS

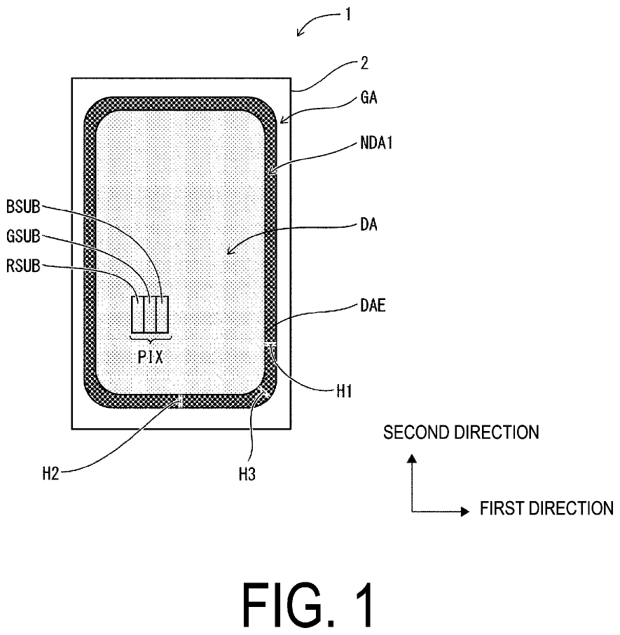

Embodiments of the disclosure will be described below with reference to FIG. 1 to FIG. 11. Hereinafter, for convenience of description, configurations having the same functions as those described in a specific embodiment are denoted by the same reference signs, and descriptions thereof will be omitted.

### First Embodiment

FIG. 1 is a schematic plan view illustrating a configuration of a display device 1 according to a first embodiment.

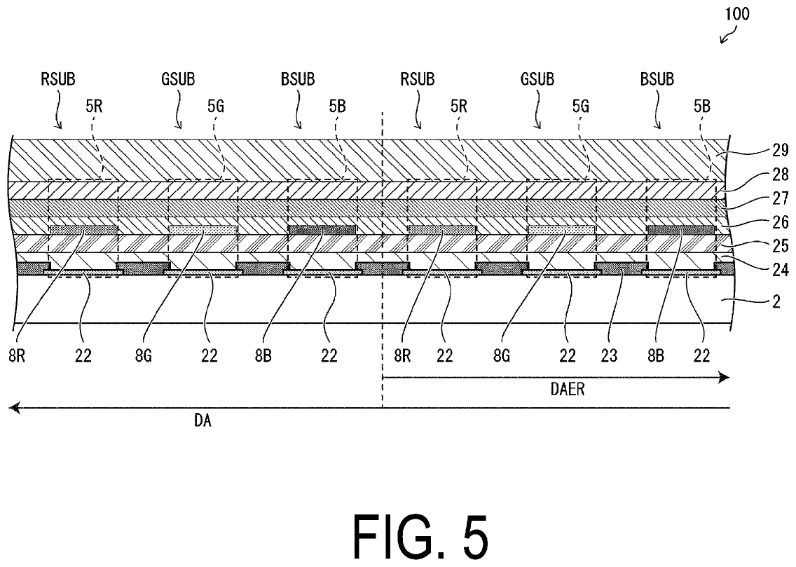

As illustrated in FIG. 1, the display device 1 includes a substrate 2, a display region DA located on the substrate 2 and provided with a plurality of pixels PIX each including a red subpixel RSUB, a green subpixel GSUB and a blue subpixel BSUB, a frame region GA located on the substrate 2 and provided outside the display region DA, and a non-display region NDA1, which is located on the substrate 2, is part of the frame region GA and continued from the display region DA, and includes a plurality of dummy subpixels (see FIG. 5) provided along an end portion DAE of the display region DA. Although not illustrated, a terminal portion, a drive circuit, and the like are provided in the frame region GA outside the non-display region NDA1. In the present embodiment, a case will be described as an example in which one pixel PIX includes the red subpixel RSUB, the green subpixel GSUB, and the blue subpixel BSUB. However, the disclosure is not limited thereto, and, for example, one pixel PIX may further include a subpixel of another color in addition to the red subpixel RSUB, green subpixel GSUB, and blue subpixel BSUB.

As illustrated in FIG. 1, since the non-display region NDA1 is included in the frame region GA, it is preferable that the non-display region NDA1 be provided not to be wider than necessary in order to achieve a narrow frame of the display device 1. Therefore, when the shape of the pixel PIX is rectangular as in the present embodiment, it is preferable that the non-display region NDA1 be formed having a width equal to or less than the length of a diagonal line of the pixel PIX. In the present embodiment, a case will be described as an example in which, in order to make the width of the non-display region NDA1 equal to or less than the length of the diagonal line of the pixel PIX, a width H1 of a rectangular right-side non-display region and a width H1 of a rectangular left-side non-display region in the non-display region NDA1 illustrated in FIG. 1 are each formed to have a size equal to a width in a first direction of the pixel PIX, a width H2 of a rectangular upper-side non-display region and a width H2 of a rectangular lower-side non-display region in the non-display region NDA1 illustrated in FIG. 1 are each formed to have a size equal to a width in a second direction of the pixel PIX, and widths of four corners of the non-display region NDA1 illustrated in FIG. 1, that is, a width H3 of a deformed portion (upper-right deformed portion) connecting the rectangular upper-side non-display region and the rectangular right-side non-display region, a width H3 of a deformed portion (lower-right deformed portion) connecting the rectangular right-side non-display region and the rectangular lower-side non-display region, a width H3 of a deformed portion (lower-left deformed portion) connecting the rectangular lower-side non-display region and the rectangular left-side non-display region, and a width H3 of a deformed portion (upper-left deformed portion) connecting the rectangular left-side non-display region and the rectangular upper-side non-display region are each formed to have a size equal to the length of the diagonal line of the pixel PIX. However, the disclosure is not limited thereto. For example, the non-display region NDA1 may be formed to be 50 μm or less in width, or is preferably formed to be 5 μm or more and 50 μm or less in width. By setting the widths of the non-display region NDA1 to be in the above-described range, it is possible to achieve a narrow frame of the display device 1 and to achieve the display device 1 configured to suppress a situation in which the light-emitting elements provided in the end portion DAE area of the display region DA emit light with luminance higher than the intended luminance and consequently bright lines appear.

In the present embodiment, a case will be described as an example in which the non-display region NDA1 is provided to surround the display region DA, but the disclosure is not limited thereto, and it is sufficient that the non-display region NDA1 is provided to surround at least part of the display region DA. For example, the non-display region NDA1 may be provided to surround only four corners of the display region DA illustrated in FIG. 1, or may be provided to surround at least one of the four sides excluding the four corners of the display region DA illustrated in FIG. 1.

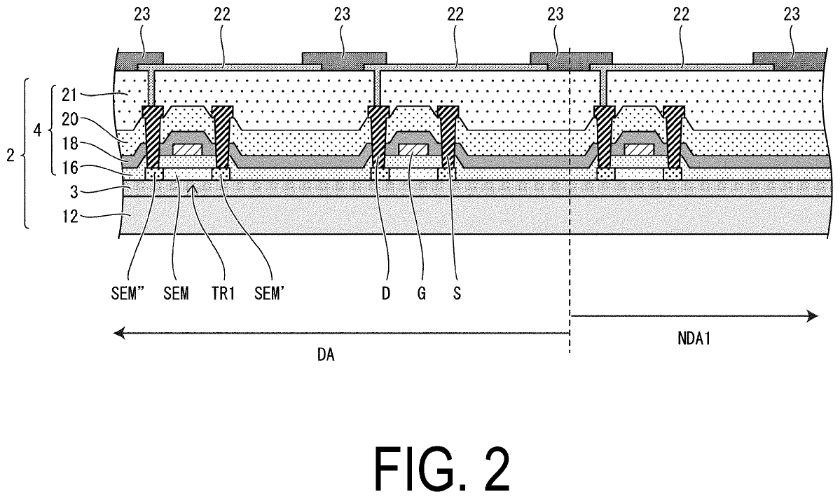

FIG. 2 is a cross-sectional view illustrating a schematic configuration of the substrate 2 provided in the display device 1 illustrated in FIG. 1.

As illustrated in FIG. 2, in the substrate 2 including a transistor TR1 and provided in the display device 1, a barrier layer 3 and a thin film transistor layer 4 including the transistor TR1 are provided on a support substrate 12 in that order from the support substrate 12 side. A lower electrode 22 and an edge cover layer 23 covering an edge portion of the lower electrode 22 are provided on a surface of the substrate 2 including the transistor TR1 in the display region DA and the non-display region NDA1 of the display device 1.

The support substrate 12 may be, for example, a resin substrate made of a resin material such as polyimide, or may be a glass substrate. In the present embodiment, the display device 1 is a flexible display device, and thus a case will be described as an example in which the resin substrate made of the resin material such as polyimide is used as the support substrate 12. However, no such limitation is intended. In a case where the display device 1 is a non-flexible display device, the glass substrate may be used as the support substrate 12.

The barrier layer 3 is a layer that inhibits foreign matters, such as water and oxygen, from entering into the transistor TR1 and the light-emitting element of each color described below. For example, the barrier layer 3 may be constituted of a silicon oxide film, a silicon nitride film or a silicon oxynitride film formed by chemical vapor deposition (CVD), or a layered film thereof.

A transistor TR1 portion in the thin film transistor layer 4 including the transistor TR1 includes a semiconductor film SEM, doped semiconductor films SEM′ and SEM″, an inorganic insulating film 16, a gate electrode G, an inorganic insulating film 18, an inorganic insulating film 20, a source electrode S, a drain electrode D, and a flattening film 21. A portion other than the transistor TR1 portion in the thin film transistor layer 4 including the transistor TR1 includes the inorganic insulating film 16, the inorganic insulating film 18, the inorganic insulating film 20, and the flattening film 21.

The semiconductor films SEM, SEM′ and SEM″ may be formed of low-temperature polysilicon (LTPS) or an oxide semiconductor (for example, an In—Ga—Zn—O based semiconductor), for example. In the present embodiment, a case will be described as an example in which the transistor TR1 has a top gate structure. However, no such limitation is intended, and the transistor TR1 may have a bottom gate structure.

The gate electrode G, the source electrode S, and the drain electrode D may be formed of a single-layer film or a layered film of a metal including, for example, at least one of aluminum, tungsten, molybdenum, tantalum, chromium, titanium, or copper.

The inorganic insulating film 16, the inorganic insulating film 18, and the inorganic insulating film 20 may be constituted of, for example, a silicon oxide film, a silicon nitride film or a silicon oxynitride film formed by, for example, chemical vapor deposition (CVD), or a layered film thereof.

The flattening film 21 may be formed of coatable organic materials such as polyimide and acrylic.

The edge cover layer 23 with insulating properties covering the edge of the lower electrode 22 is formed, for example, by applying an organic material such as polyimide or acrylic, and then patterning the organic material by photolithography.

As illustrated in FIG. 2, a control circuit including the transistor TR1 for controlling each of a plurality of the lower electrodes 22 is provided in the thin film transistor layer 4 including the transistor TR1.

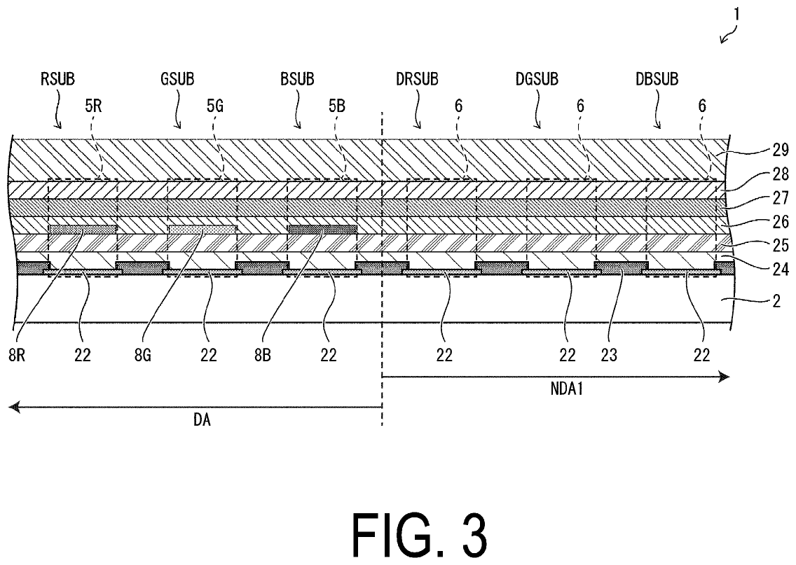

FIG. 3 is a cross-sectional view illustrating a schematic configuration of a red light-emitting element 5R, a green light-emitting element 5G and a blue light-emitting element 5B provided in the display region DA, and a non-emitting charge transfer element 6 provided in the non-display region NDA1 of the display device 1 according to the first embodiment.

As illustrated in FIG. 3, the red subpixel RSUB provided in the display region DA of the display device 1 includes the red light-emitting element 5R including a red light-emitting layer 8R, the green subpixel GSUB provided in the display region DA of the display device 1 includes the green light-emitting element 5G including a green light-emitting layer 8G, and the blue subpixel BSUB provided in the display region DA of the display device 1 includes the blue light-emitting element 5B including a blue light-emitting layer 8B. The red light-emitting element 5R includes the lower electrode 22 as an anode, a hole injection layer 24, a hole transport layer 25, the red light-emitting layer 8R, an electron transport layer 26, an electron injection layer 27, and an upper electrode 28 as a cathode; the green light-emitting element 5G includes the lower electrode 22 as an anode, the hole injection layer 24, the hole transport layer 25, the green light-emitting layer 8G, the electron transport layer 26, the electron injection layer 27, and the upper electrode 28 as a cathode; and the blue light-emitting element 5B includes the lower electrode 22 as an anode, the hole injection layer 24, the hole transport layer 25, the blue light-emitting layer 8B, the electron transport layer 26, the electron injection layer 27, and the upper electrode 28 as a cathode.

The hole injection layer 24 and the hole transport layer 25 are provided as a charge transfer layer (hole transfer layer) which is a common layer formed over the entire surface of the display region DA and non-display region NDA1 between the lower electrode 22 and the red light-emitting layer 8R provided in the red light-emitting element 5R, between the lower electrode 22 and the green light-emitting layer 8G provided in the green light-emitting element 5G, and between the lower electrode 22 and the blue light-emitting layer 8B provided in the blue light-emitting element 5B of the display device 1 illustrated in FIG. 3. In the present embodiment, a case will be described as an example in which both the hole injection layer 24 and the hole transport layer 25 are provided as a charge transfer layer (hole transfer layer) which is a common layer formed over the entire surface of the display region DA and non-display region NDA1, but the disclosure is not limited thereto. Only one of the hole injection layer 24 and the hole transport layer 25 may be provided as a charge transfer layer (hole transfer layer) which is a common layer formed over the entire surface of the display region DA and non-display region NDA1.

A sealing layer 29 provided on the upper electrode 28 is a light-transmitting film, and may be formed of an inorganic sealing film covering the upper electrode 28, an organic film serving as an upper layer overlying the inorganic sealing film, and an inorganic sealing film serving as an upper layer overlying the organic film, for example. The sealing layer 29 inhibits foreign matters, such as water and oxygen, from entering into the light-emitting element of each color.

In the present embodiment, as illustrated in FIG. 3, a case will be described as an example in which, in the red subpixel RSUB provided in the display region DA of the display device 1, there is provided the red light-emitting element 5R having an orderly layered structure where the lower electrode 22 as an anode, the hole injection layer 24, the hole transport layer 25, the red light-emitting layer 8R, the electron transport layer 26, the electron injection layer 27, and the upper electrode 28 as a cathode are layered on the substrate 2 in that order from the substrate 2 side; in the green subpixel GSUB provided in the display region DA, there is provided the green light-emitting element 5G having an orderly layered structure where the lower electrode 22 as an anode, the hole injection layer 24, the hole transport layer 25, the green light-emitting layer 8G, the electron transport layer 26, the electron injection layer 27, and the upper electrode 28 as a cathode are layered on the substrate 2 in that order from the substrate 2 side; and in the blue subpixel BSUB provided in the display region DA, there is provided the blue light-emitting element 5B having an orderly layered structure where the lower electrode 22 as an anode, the hole injection layer 24, the hole transport layer 25, the blue light-emitting layer 8B, the electron transport layer 26, the electron injection layer 27, and the upper electrode 28 as a cathode are layered on the substrate 2 in that order from the substrate 2 side. However, the disclosure is not limited thereto. For example, in each of the red light-emitting element 5R, the green light-emitting element 5G, and the blue light-emitting element 5B, one of the hole injection layer 24 and the hole transport layer 25 formed over the entire surface of the display region DA and non-display region NDA1 as a charge transfer layer (hole transfer layer) which is a common layer may be omitted. In this case, one of the hole injection layer 24 and the hole transport layer 25 may also be omitted in the non-emitting charge transfer element 6 provided in the non-display region NDA1. In each of the red light-emitting element 5R, the green light-emitting element 5G, and the blue light-emitting element 5B, at least one of the electron transport layer 26 and the electron injection layer 27 may be omitted. In this case, at least one of the electron transport layer 26 and the electron injection layer 27 may also be omitted in the non-emitting charge transfer element 6 provided in the non-display region NDA1.

Each of the red light-emitting element 5R, the green light-emitting element 5G, and the blue light-emitting element 5B illustrated in FIG. 3 may be a top-emitting light-emitting element in which the lower electrode 22 serving as an anode is made of an electrode material that reflects visible light, the upper electrode 28 serving as a cathode is made of an electrode material that transmits visible light, and light is emitted from the side of the upper electrodes 28 located at the upper side, or may be a bottom-emitting light-emitting element in which the lower electrode 22 serving as an anode is made of an electrode material that transmits visible light, the upper electrode 28 serving as a cathode is made of an electrode material that reflects visible light, and light is emitted from the side of the substrate 2 located at the lower side.

The electrode material that reflects visible light is not particularly limited as long as the material can reflect visible light and has electrical conductivity. Examples thereof include metal materials such as Al, Mg, Li and Ag, alloys of these metal materials, a layered body of the above metal materials and transparent metal oxides (for example, indium tin oxide, indium zinc oxide, and indium gallium zinc oxide), and a layered body of the alloys and the transparent metal oxides.

On the other hand, the electrode material that transmits visible light is not particularly limited as long as the material can transmit visible light and has electrical conductivity. Examples thereof include a transparent metal oxide (for example, indium tin oxide, indium zinc oxide, or indium gallium zinc oxide), a thin film made of a metal material such as Al, Mg, Li or Ag, and a conductive nano material such as a silver nanowire or a carbon nanotube.

A material to be used for the hole injection layer 24 is not particularly limited as long as the material is a hole injection material capable of stabilizing the injection of positive holes into the red light-emitting layer 8R, the green light-emitting layer 8G, and the blue light-emitting layer 8B. For example, PEDOT may be cited as an example, but the disclosure is not limited thereto.

A material to be used for the hole transport layer 25 is not particularly limited as long as the material is a hole transport material capable of transporting positive holes injected from the lower electrode 22 serving as an anode into the red light-emitting layer 8R, the green light-emitting layer 8G, and the blue light-emitting layer 8B. Among these, a hole transport material having high hole mobility is preferable. For example, TFB (ADS) may be cited as an example, but the disclosure is not limited thereto. Furthermore, the hole transport material is preferably a material (electron blocking material) capable of preventing the penetration of electrons that have traveled from the upper electrode 28 serving as a cathode. This makes it possible to raise recombination efficiency of positive holes and electrons in the red light-emitting layer 8R, green light-emitting layer 8G, and blue light-emitting layer 8B.

A material to be used for the electron transport layer 26 is not particularly limited as long as the material is an electron transport material capable of transporting electrons injected from the upper electrode 28 serving as a cathode into the red light-emitting layer 8R, the green light-emitting layer 8G, and the blue light-emitting layer 8B. Among these, the electron transport material having high electron mobility is preferable. For example, ZnMgO may be cited as an example, but the disclosure is not limited thereto. Furthermore, the electron transport material is preferably a material (hole blocking material) capable of preventing the penetration of positive holes that have traveled from the lower electrode 22 serving as an anode. This makes it possible to raise recombination efficiency of the positive holes and the electrons in the red light-emitting layer 8R, green light-emitting layer 8G, and blue light-emitting layer 8B.

A material to be used for the electron injection layer 27 is not particularly limited as long as the material is an electron injection material capable of stabilizing the injection of electrons into the red light-emitting layer 8R, the green light-emitting layer 8G, and the blue light-emitting layer 8B. Examples of the electron injection material include alkali metals or alkaline earth metals, oxides of alkali metals or alkaline earth metals, fluorides of alkali metals or alkaline earth metals, and organic complexes of alkali metals, such as aluminum, strontium, calcium, lithium, cesium, magnesium oxide, aluminum oxide, strontium oxide, lithium oxide, lithium fluoride, magnesium fluoride, strontium fluoride, calcium fluoride, barium fluoride, cesium fluoride, polymethylmethacrylate, and sodium polystyrene sulfonate.

In the present embodiment, as illustrated in FIG. 3, a case will be described as an example in which, in a first dummy subpixel DRSUB provided in the non-display region NDA1 of the display device 1, there is provided the non-emitting charge transfer element 6 having an orderly layered structure where the lower electrode 22 as an anode, the hole injection layer 24, the hole transport layer 25, the electron transport layer 26, the electron injection layer 27, and the upper electrode 28 as a cathode are layered on the substrate 2 in that order from the substrate 2 side; in a second dummy subpixel DGSUB provided in the non-display region NDA1, there is provided the non-emitting charge transfer element 6 having an orderly layered structure where the lower electrode 22 as an anode, the hole injection layer 24, the hole transport layer 25, the electron transport layer 26, the electron injection layer 27, and the upper electrode 28 as a cathode are layered on the substrate 2 in that order from the substrate 2 side; and in a third dummy subpixel DBSUB provided in the non-display region NDA1, there is provided the non-emitting charge transfer element 6 having an orderly layered structure where the lower electrode 22 as an anode, the hole injection layer 24, the hole transport layer 25, the electron transport layer 26, the electron injection layer 27, and the upper electrode 28 as a cathode are layered on the substrate 2 in that order from the substrate 2 side. However, the disclosure is not limited thereto. For example, the non-display region NDA1 of the display device 1 may be provided with only one or two of the first dummy subpixel DRSUB, the second dummy subpixel DGSUB, and the third dummy subpixel DBSUB each including the corresponding non-emitting charge transfer element 6 having the orderly layered structure. One of the hole injection layer 24 and the hole transport layer 25 may be omitted in the non-emitting charge transfer element 6 having the orderly layered structure. At least one of the electron transport layer 26 and the electron injection layer 27 may be omitted in the non-emitting charge transfer element 6 having the orderly layered structure.

In the present embodiment, the charge transfer layer (hole transfer layer) provided in the display region DA of the display device 1 and the charge transfer layer (hole transfer layer) provided in the non-display region NDA1 of the display device 1 are formed of the same material. That is, when the charge transfer layer (hole transfer layer) provided in the display region DA and the non-display region NDA1 is formed of only the hole injection layer 24, the hole injection layer 24 provided in the display region DA and the hole injection layer 24 provided in the non-display region NDA1 are formed of the same material. When the charge transfer layer (hole transfer layer) provided in the display region DA and the non-display region NDA1 is formed of only the hole transport layer 25, the hole transport layer 25 provided in the display region DA and the hole transport layer 25 provided in the non-display region NDA1 are formed of the same material. When the charge transfer layer (hole transfer layer) provided in the display region DA and the non-display region NDA1 is formed of the hole injection layer 24 and the hole transport layer 25, the hole injection layer 24 and the hole transport layer 25 provided in the display region DA are formed of the same materials as the hole injection layer 24 and the hole transport layer 25 provided in the non-display region NDA1.

Without being limited thereto, the charge transfer layer (hole transfer layer) provided in the display region DA of the display device 1 and the charge transfer layer (hole transfer layer) provided in the non-display region NDA1 of the display device 1 may be formed of different materials as long as positive holes can transfer from the display region DA to the non-display region NDA1.

In the present embodiment, a case will be described as an example in which the red subpixel (first subpixel) RSUB and the first dummy subpixel DRSUB are formed in the same shape, the green subpixel (second subpixel) GSUB and the second dummy subpixel DGSUB are formed in the same shape, and the blue subpixel (third subpixel) BSUB and the third dummy subpixel DBSUB are formed in the same shape. However, the disclosure is not limited thereto. For example, it is sufficient that the dummy subpixels provided in the non-display region NDA1 include at least one of the first dummy subpixel DRSUB formed in the same shape as the red subpixel (first subpixel) RSUB, the second dummy subpixel DGSUB formed in the same shape as the green subpixel (second subpixel) GSUB, or the third dummy subpixel DBSUB formed in the same shape as the blue subpixel (third subpixel) BSUB. Further, the subpixels provided in the display region DA and the dummy subpixels provided in the non-display region NDA1 may have different shapes.

As illustrated in FIG. 3, according to the display device 1, positive holes H⁺ having transferred from the display region DA to the non-display region NDA1 through at least one of the hole injection layer 24 and the hole transport layer 25 as a charge transfer layer (hole transfer layer) are unable to go out of the non-display region NDA1 and are accumulated in the non-display region NDA1; the positive holes H⁺ accumulated as discussed above transfer toward the upper electrode 28 in the non-emitting charge transfer element 6 provided in the non-display region NDA1, thereby making it possible to suppress a situation in which the positive holes H⁺ are kept being accumulated without causing the occurrence of bright lines in the non-display region NDA1. Since none of the red light-emitting layer 8R, the green light-emitting layer 8G and the blue light-emitting layer 8B are provided in the non-emitting charge transfer element 6, even when the positive holes H⁺ transfer through the non-emitting charge transfer element 6, no bright line is generated in the non-display region NDA1 due to light emission with luminance higher than the intended luminance.

A method for manufacturing the display device 1 illustrated in FIG. 3 includes:
a step of forming the plurality of lower electrodes 22 in each of the display region DA located on the substrate 2 and the non-display region NDA1 located on the substrate 2 and continued from the display region DA;
a step of forming the upper electrode 28 in the display region DA and the non-display region NDA1 after the step of forming the plurality of lower electrodes 22;
a step of forming a light-emitting layer only in the display region DA between the step of forming the plurality of lower electrodes 22 and the step of forming the upper electrode 28; and
a step of forming a charge transfer layer (hole transfer layer) made of one layer in the display region DA and the non-display region NDA1 between the step of forming the plurality of lower electrodes 22 and the step of forming a light-emitting layer.

According to the display device 1 manufactured by the above-described manufacturing method, positive holes H⁺ having transferred from the display region DA to the non-display region NDA1 through at least one of the hole injection layer 24 and the hole transport layer 25 as a charge transfer layer (hole transfer layer) are unable to go out of the non-display region NDA1 and are accumulated in the non-display region NDA1; the positive holes H⁺ accumulated as discussed above transfer toward the upper electrode 28 in the non-emitting charge transfer element 6 provided in the non-display region NDA1, thereby making it possible to suppress a situation in which the positive holes H⁺ are kept being accumulated without causing the occurrence of bright lines in the non-display region NDA1.

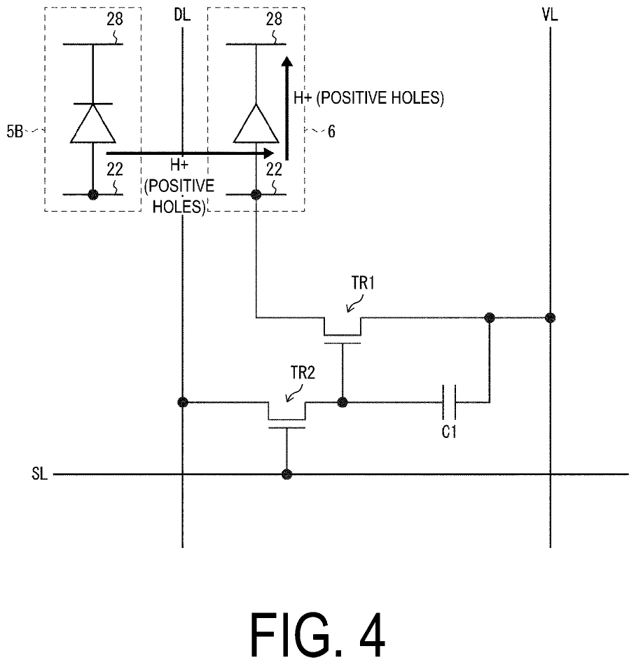

FIG. 4 is a diagram illustrating a circuit near a boundary between the display region DA and the non-display region NDA1 of the display device 1 illustrated in FIG. 3.

FIG. 4 illustrates a schematic circuit configuration of a drive circuit of the blue subpixel BSUB including the blue light-emitting element 5B provided in the display region DA of the display device 1 and a drive circuit of the first dummy subpixel DRSUB including the non-emitting charge transfer element 6 provided in the non-display region NDA1 of the display device 1 adjacent to the blue light-emitting element 5B. The drive circuit of the blue subpixel BSUB including the blue light-emitting element 5B and the drive circuit of the first dummy subpixel DRSUB including the non-emitting charge transfer element 6 are provided on the substrate 2 illustrated in FIG. 3.

As illustrated in FIG. 4, the drive circuit of the first dummy subpixel DRSUB including the non-emitting charge transfer element 6 provided in the non-display region NDA1 of the display device 1 adjacent to the blue light-emitting element 5B includes one non-emitting charge transfer element 6, two transistors TR1 and TR2, and one holding capacitor C1. Although not illustrated, the drive circuit of the blue subpixel BSUB including the blue light-emitting element 5B provided in the display region DA of the display device 1 has the same configuration as the drive circuit of the first dummy subpixel DRSUB including the non-emitting charge transfer element 6 described above except that the blue light-emitting element 5B is included instead of the non-emitting charge transfer element 6.

In the drive circuit of the first dummy subpixel DRSUB including the non-emitting charge transfer element 6 illustrated in FIG. 4, the drain electrode of the transistor TR1 serving as a drive transistor is electrically connected to the lower electrode 22 of the non-emitting charge transfer element 6, the gate electrode of the transistor TR1 is electrically connected to one of the electrodes of the holding capacitor C1 and the drain electrode of the transistor TR2 serving as a selecting transistor, and the source electrode of the transistor TR1 is electrically connected to the other one of the electrodes of the holding capacitor C1 and an ELVDD wiring line VL supplied with a high-level power supply voltage ELVDD from a power source circuit (not illustrated). Although not illustrated, the upper electrode 28 of the blue light-emitting element 5B and the upper electrode 28 of the non-emitting charge transfer element 6 are electrically connected to an ELVSS wiring line supplied with a low-level power supply voltage ELVSS from a power source circuit. The source electrode of the transistor TR2 serving as a selecting transistor is electrically connected to a data signal line DL supplied with a data signal that is output from a data-side drive circuit (not illustrated), the gate electrode of the transistor TR2 is electrically connected to a scanning signal line SL supplied with a scanning signal that is output from a scanning-side drive circuit (not illustrated), and the drain electrode of the transistor TR2 is electrically connected to the gate electrode of the transistor TR1 and the one of the electrodes of the holding capacitor C1.

In the display device 1 illustrated in FIG. 3 and FIG. 4, in which the hole injection layer 24 and the hole transport layer 25 are provided as a charge transfer layer (hole transfer layer) which is a common layer formed over the entire surface of the display region DA, since the non-emitting charge transfer element 6 is provided in the non-display region NDA1 of the display device 1 as described above, it is possible to suppress the occurrence of bright lines in the end portion area of the display region DA provided near the non-display region NDA1 of the display device 1.

In the present embodiment, a case has been described as an example in which no specific voltage is applied to the data signal line DL of the drive circuit for the first dummy subpixel DRSUB including the non-emitting charge transfer element 6 illustrated in FIG. 4, a data signal line DL of the drive circuit for the second dummy subpixel DGSUB including the non-emitting charge transfer element 6 (not illustrated), and a data signal line DL of the drive circuit for the third dummy subpixel DBSUB including the non-emitting charge transfer element 6 (not illustrated). However, the disclosure is not limited thereto. From the viewpoint of transferring the positive holes H⁺ accumulated in the non-display region NDA1 toward the upper electrodes 28 in accordance with the timing of applying the voltage, a predetermined voltage may be applied to each of the data signal lines DL of the drive circuits for the first dummy subpixel DRSUB, second dummy subpixel DGSUB, and third dummy subpixel DBSUB. For example, a voltage equal to or higher than 2 V and equal to or lower than 8 V is preferably applied, and a voltage of 2 V is more preferably applied. The above-described voltage may be applied at predetermined intervals.

FIG. 5 is a cross-sectional view illustrating a schematic configuration of a display device 100 according to a comparative example in which the red light-emitting element 5R, the green light-emitting element 5G, and the blue light-emitting element 5B provided in an end portion area DAER of the display region DA emit light with luminance higher than the intended luminance and consequently bright lines appear.

As illustrated in FIG. 5, the red subpixel RSUB provided in the display region DA including the end portion area DAER of the display region DA in the display device 100 includes the red light-emitting element 5R including the red light-emitting layer 8R, the green subpixel GSUB provided in the display region DA including the end portion area DAER of the display region DA in the display device 100 includes the green light-emitting element 5G including the green light-emitting layer 8G, and the blue subpixel BSUB provided in the display region DA including the end portion area DAER of the display region DA in the display device 100 includes the blue light-emitting element 5B including the blue light-emitting layer 8B. The red light-emitting element 5R includes the lower electrode 22 as an anode, the hole injection layer 24, the hole transport layer 25, the red light-emitting layer 8R, the electron transport layer 26, the electron injection layer 27, and the upper electrode 28 as a cathode; the green light-emitting element 5G includes the lower electrode 22 as an anode, the hole injection layer 24, the hole transport layer 25, the green light-emitting layer 8G, the electron transport layer 26, the electron injection layer 27, and the upper electrode 28 as a cathode; and the blue light-emitting element 5B includes the lower electrode 22 as an anode, the hole injection layer 24, the hole transport layer 25, the blue light-emitting layer 8B, the electron transport layer 26, the electron injection layer 27, and the upper electrode 28 as a cathode.

The hole injection layer 24 and the hole transport layer 25 are provided as a charge transfer layer (hole transfer layer) which is a common layer formed over the entire surface of the display region DA between the lower electrode 22 and the red light-emitting layer 8R provided in the red light-emitting element 5R, between the lower electrode 22 and the green light-emitting layer 8G provided in the green light-emitting element 5G, and between the lower electrode 22 and the blue light-emitting layer 8B provided in the blue light-emitting element 5B of the display device 100 according to the comparative example illustrated in FIG. 5.

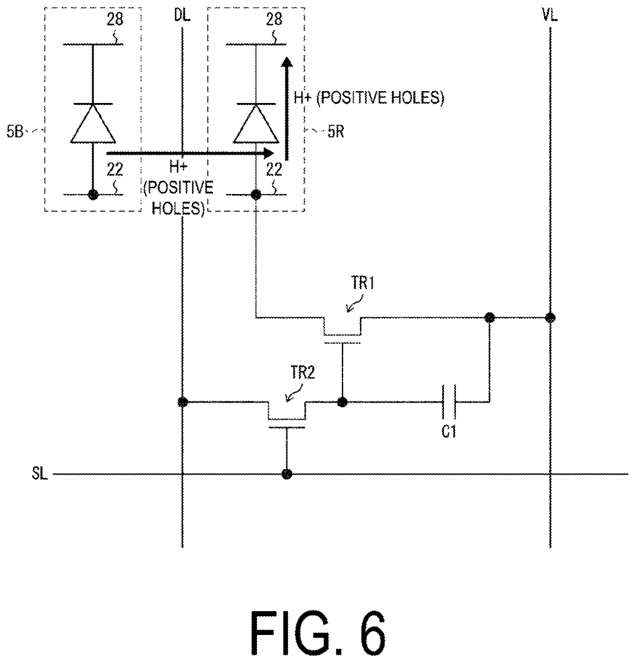

FIG. 6 is a circuit diagram for explaining a reason why a bright line appears in the end portion area DAER of the display region DA of the display device 100 according to the comparative example illustrated in FIG. 5. FIG. 6 illustrates a schematic circuit configuration of a drive circuit of the red subpixel RSUB including the red light-emitting element 5R provided in the end portion area DAER of the display region DA and the blue light-emitting element 5B disposed adjacent to the red light-emitting element 5R, in the display device 100 according to the comparative example illustrated in FIG. 5.

As illustrated in FIG. 6, the drive circuit of the red subpixel RSUB including the red light-emitting element 5R provided in the end portion area DAER of the display region DA in the display device 100 according to the comparative example includes one light-emitting element, two transistors TR1 and TR2, and one holding capacitor C1. The transistor TR1 is a drive transistor and the transistor TR2 is a selecting transistor. Although not illustrated, the drive circuit of the green subpixel GSUB including the green light-emitting element 5G provided in the end portion area DAER of the display region DA in the display device 100 according to the comparative example and the drive circuit of the blue subpixel BSUB including the blue light-emitting element 5B provided in the end portion area DAER of the display region DA in the display device 100 according to the comparative example also have the same configuration as the configuration described above.

In the drive circuit of the red subpixel RSUB including the red light-emitting element 5R illustrated in FIG. 6, the drain electrode of the transistor TR1 serving as a drive transistor is electrically connected to the lower electrode 22 of the red light-emitting element 5R, the gate electrode of the transistor TR1 is electrically connected to one of the electrodes of the holding capacitor C1 and the drain electrode of the transistor TR2 serving as a selecting transistor, and the source electrode of the transistor TR1 is electrically connected to the other one of the electrodes of the holding capacitor C1 and an ELVDD wiring line VL supplied with a high-level power supply voltage ELVDD from a power source circuit (not illustrated). The source electrode of the transistor TR2 serving as a selecting transistor is electrically connected to a data signal line DL supplied with a data signal that is output from a data-side drive circuit (not illustrated), the gate electrode of the transistor TR2 is electrically connected to a scanning signal line SL supplied with a scanning signal that is output from a scanning-side drive circuit (not illustrated), and the drain electrode of the transistor TR2 is electrically connected to the gate electrode of the transistor TR1 and the one of the electrodes of the holding capacitor C1.

In the display device 100 according to the comparative example illustrated in FIG. 5, in which the hole injection layer 24 and the hole transport layer 25 are provided as a charge transfer layer (hole transfer layer) which is a common layer formed over the entire surface of the display region DA, a bright line appears in the end portion area DAER of the display region DA. The inventors of the disclosure consider that one of the reasons for the occurrence of the above-mentioned bright line is as follows. As illustrated in FIG. 5 and FIG. 6, the positive holes H⁺ having transferred to the end portion area DAER of the display region DA through the hole injection layer 24 and hole transport layer 25 as the charge transfer layer (hole transfer layer) are unable to go out of the end portion area DAER of the display region DA and are accumulated in the end portion area DAER thereof, and in the light-emitting element provided in the end portion area DAER of the display region DA, the positive holes H⁺ accumulated as discussed above transfer toward the upper electrode 28 and light is emitted with luminance higher than the intended luminance. In the display device 100 according to the comparative example, a case has been described as an example in which the hole injection layer 24 and the hole transport layer 25 are provided as the charge transfer layer (hole transfer layer) which is a common layer formed over the entire surface of the display region DA. However, without being limited thereto, in a case where only one of the hole injection layer 24 and the hole transport layer 25 is provided, a bright line also appears similarly in the end portion area DAER of the display region DA.

### Second Embodiment

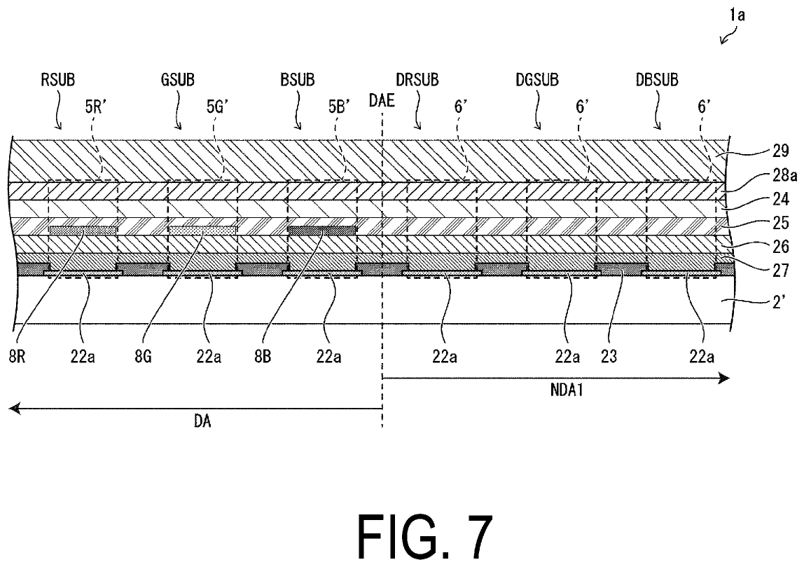

Next, a second embodiment of the disclosure will be described with reference to FIG. 7 to FIG. 10. The second embodiment differs from the first embodiment in that a non-emitting charge transfer element 6′ having an inverted layered structure is provided in a non-display region NDA1 of a display device 1a of the present embodiment. The others are as described in the first embodiment. For convenience of description, members having the same functions as those illustrated in diagrams of the first embodiment are denoted by the same reference signs, and descriptions thereof are omitted.

FIG. 7 is a cross-sectional view illustrating a schematic configuration of a red light-emitting element 5R′, a green light-emitting element 5G′ and a blue light-emitting element 5B′ provided in a display region DA, and the non-emitting charge transfer element 6′ provided in the non-display region NDA1 of the display device 1a according to the second embodiment.

In the present embodiment, as illustrated in FIG. 7, a case will be described as an example in which, in a red subpixel RSUB provided in the display region DA of the display device 1a, there is provided the red light-emitting element 5R′ having an inverted layered structure where a lower electrode 22a as a cathode, an electron injection layer 27, an electron transport layer 26, a red light-emitting layer 8R, a hole transport layer 25, and a hole injection layer 24 are layered on a substrate 2′ in that order from the substrate 2′ side; in a green subpixel GSUB provided in the display region DA, there is provided the green light-emitting element 5G′ having an inverted layered structure where the lower electrode 22a as a cathode, the electron injection layer 27, the electron transport layer 26, a green light-emitting layer 8G, the hole transport layer 25, and the hole injection layer 24 are layered on the substrate 2′ in that order from the substrate 2′ side; and in a blue subpixel BSUB provided in the display region DA, there is provided the blue light-emitting element 5B′ having an inverted layered structure where the lower electrode 22a as a cathode, the electron injection layer 27, the electron transport layer 26, a blue light-emitting layer 8B, the hole transport layer 25, and the hole injection layer 24 are layered on the substrate 2′ in that order from the substrate 2′ side. However, the disclosure is not limited thereto. For example, in each of the red light-emitting element 5R′, the green light-emitting element 5G′, and the blue light-emitting element 5B′, one of the electron injection layer 27 and the electron transport layer 26 formed over the entire surface of the display region DA and non-display region NDA1 as a charge transfer layer (electron transfer layer) which is a common layer may be omitted. In this case, one of the electron injection layer 27 and the electron transport layer 26 may also be omitted in the non-emitting charge transfer element 6′ provided in the non-display region NDA1. In each of the red light-emitting element 5R′, the green light-emitting element 5G′, and the blue light-emitting element 5B′, at least one of the hole transport layer 25 and the hole injection layer 24 may be omitted. In this case, at least one of the hole transport layer 25 and the hole injection layer 24 may also be omitted in the non-emitting charge transfer element 6′ provided in the non-display region NDA1.

In the present embodiment, as illustrated in FIG. 7, a case will be described as an example in which, in a first dummy subpixel DRSUB provided in the non-display region NDA1 of the display device 1a, there is provided the non-emitting charge transfer element 6′ having an inverted layered structure where the lower electrode 22a as a cathode, the electron injection layer 27, the electron transport layer 26, the hole transport layer 25, the hole injection layer 24, and an upper electrode 28a as an anode are layered on the substrate 2′ in that order from the substrate 2′ side; in a second dummy subpixel DGSUB provided in the non-display region NDA1, there is provided the non-emitting charge transfer element 6′ having an inverted layered structure where the lower electrode 22a as a cathode, the electron injection layer 27, the electron transport layer 26, the hole transport layer 25, the hole injection layer 24, and the upper electrode 28a as an anode are layered on the substrate 2′ in that order from the substrate 2′ side; and in a third dummy subpixel DBSUB provided in the non-display region NDA1, there is provided the non-emitting charge transfer element 6′ having an inverted layered structure where the lower electrode 22a as a cathode, the electron injection layer 27, the electron transport layer 26, the hole transport layer 25, the hole injection layer 24, and the upper electrode 28a as an anode are layered on the substrate 2′ in that order from the substrate 2′ side. However, the disclosure is not limited thereto. For example, the non-display region NDA1 of the display device 1a may be provided with only one or two of the first dummy subpixel DRSUB, the second dummy subpixel DGSUB, and the third dummy subpixel DBSUB each including the non-emitting charge transfer element 6′ having the inverted layered structure described above. One of the electron transport layer 26 and the electron injection layer 27 may be omitted in the non-emitting charge transfer element 6′ having the inverted layered structure. At least one of the hole injection layer 24 and the hole transport layer 25 may be omitted in the non-emitting charge transfer element 6′ having the inverted layered structure.

In the present embodiment, the charge transfer layer (electron transfer layer) provided in the display region DA of the display device 1a and the charge transfer layer (electron transfer layer) provided in the non-display region NDA1 of the display device 1a are formed of the same material. That is, when the charge transfer layer (electron transfer layer) provided in the display region DA and the non-display region NDA1 is formed of only the electron injection layer 27, the electron injection layer 27 provided in the display region DA and the electron injection layer 27 provided in the non-display region NDA1 are formed of the same material. When the charge transfer layer (electron transfer layer) provided in the display region DA and the non-display region NDA1 is formed of only the electron transport layer 26, the electron transport layer 26 provided in the display region DA and the electron transport layer 26 provided in the non-display region NDA1 are formed of the same material. When the charge transfer layer (electron transfer layer) provided in the display region DA and the non-display region NDA1 is formed of the electron injection layer 27 and the electron transport layer 26, the electron injection layer 27 and the electron transport layer 26 provided in the display region DA are formed of the same materials as the electron injection layer 27 and the electron transport layer 26 provided in the non-display region NDA1.

Without being limited thereto, the charge transfer layer (electron transfer layer) provided in the display region DA of the display device 1a and the charge transfer layer (electron transfer layer) provided in the non-display region NDA1 of the display device 1a may be formed of different materials as long as electrons can transfer from the display region DA to the non-display region NDA1.

As illustrated in FIG. 7, according to the display device 1a, electrons e having transferred from the display region DA to the non-display region NDA1 through at least one of the electron injection layer 27 and the electron transport layer 26 as a charge transfer layer (electron transfer layer) are unable to go out of the non-display region NDA1 and are accumulated in the non-display region NDA1; in the non-emitting charge transfer element 6′ provided in the non-display region NDA1, the electrons e accumulated as discussed above transfer toward the upper electrode 28a, thereby making it possible to suppress a situation in which the electrons e are kept being accumulated without causing the occurrence of bright lines in the non-display region NDA1. Since none of the red light-emitting layer 8R, the green light-emitting layer 8G and the blue light-emitting layer 8B are provided in the non-emitting charge transfer element 6′, even when the electrons e transfer through the non-emitting charge transfer element 6′, no bright line is generated in the non-display region NDA1 due to light emission with luminance higher than the intended luminance.

A method for manufacturing the display device 1a illustrated in FIG. 7 includes:
a step of forming a plurality of the lower electrodes 22a in each of the display region DA located on the substrate 2′ and the non-display region NDA1 located on the substrate 2′ and continued from the display region DA;
a step of forming the upper electrode 28a in the display region DA and the non-display region NDA1 after the step of forming a plurality of the lower electrodes 22a;
a step of forming a light-emitting layer only in the display region DA between the step of forming a plurality of the lower electrodes 22a and the step of forming the upper electrode 28a; and
a step of forming a charge transfer layer (electron transfer layer) made of one layer in the display region DA and the non-display region NDA1 between the step of forming a plurality of the lower electrodes 22a and the step of forming a light-emitting layer.

According to the display device 1a manufactured by the manufacturing method described above, the electrons e having transferred from the display region DA to the non-display region NDA1 through at least one of the electron injection layer 27 and the electron transport layer 26 as a charge transfer layer (electron transfer layer) are unable to go out of the non-display region NDA1 and are accumulated in the non-display region NDA1; the electrons e accumulated as discussed above transfer toward the upper electrode 28a in the non-emitting charge transfer element 6′ provided in the non-display region NDA1, thereby making it possible to suppress a situation in which the electrons e are kept being accumulated without causing the occurrence of bright lines in the non-display region NDA1.

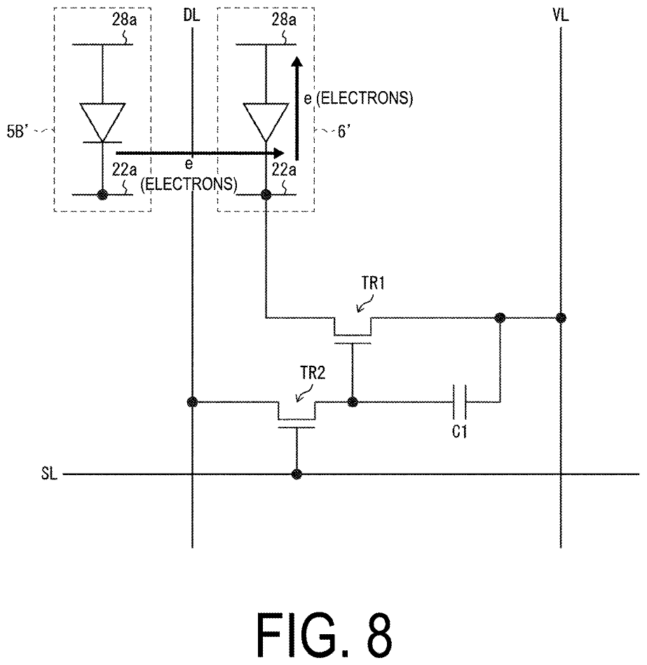

FIG. 8 is a diagram illustrating a circuit near a boundary between the display region DA and the non-display region NDA1 of the display device 1a illustrated in FIG. 7.

FIG. 8 illustrates a schematic circuit configuration of the drive circuit of the blue subpixel BSUB including the blue light-emitting element 5B′ provided in the display region DA of the display device 1a and a drive circuit of the first dummy subpixel DRSUB including the non-emitting charge transfer element 6′ provided in the non-display region NDA1 of the display device 1a adjacent to the blue light-emitting element 5B′. The drive circuit of the blue subpixel BSUB including the blue light-emitting element 5B′ and the drive circuit of the first dummy subpixel DRSUB including the non-emitting charge transfer element 6′ are provided on the substrate 2′ illustrated in FIG. 7. The circuit configuration of the drive circuit of the blue subpixel BSUB including the blue light-emitting element 5B′ and the drive circuit of the first dummy subpixel DRSUB including the non-emitting charge transfer element 6′ is described in the first embodiment, and therefore the description thereof is omitted here.

In the display device 1a illustrated in FIG. 7 and FIG. 8, in which the electron injection layer 27 and the electron transport layer 26 are provided as a charge transfer layer (electron transfer layer) which is a common layer formed over the entire surface of the display region DA, since the non-emitting charge transfer element 6′ is provided in the non-display region NDA1 of the display device 1a as described above, it is possible to suppress the occurrence of bright lines in the end portion area of the display region DA provided near the non-display region NDA1 of the display device 1a.

In the present embodiment, a case has been described as an example in which no specific voltage is applied to a data signal line DL of the drive circuit for the first dummy subpixel DRSUB including the non-emitting charge transfer element 6′ illustrated in FIG. 8, a data signal line DL of the drive circuit for the second dummy subpixel DGSUB including the non-emitting charge transfer element 6′ (not illustrated), and a data signal line DL of the drive circuit for the third dummy subpixel DBSUB including the non-emitting charge transfer element 6′ (not illustrated). However, the disclosure is not limited thereto. From the viewpoint of transferring the electrons e accumulated in the non-display region NDA1 toward the upper electrodes 28a in accordance with the timing of applying the voltage, a predetermined voltage may be applied to each of the data signal lines DL of the drive circuits for the first dummy subpixel DRSUB, second dummy subpixel DGSUB, and third dummy subpixel DBSUB. For example, a voltage equal to or higher than 2 V and equal to or lower than 8 V is preferably applied, and a voltage of 2 V is more preferably applied. The above-described voltage may be applied at predetermined intervals.

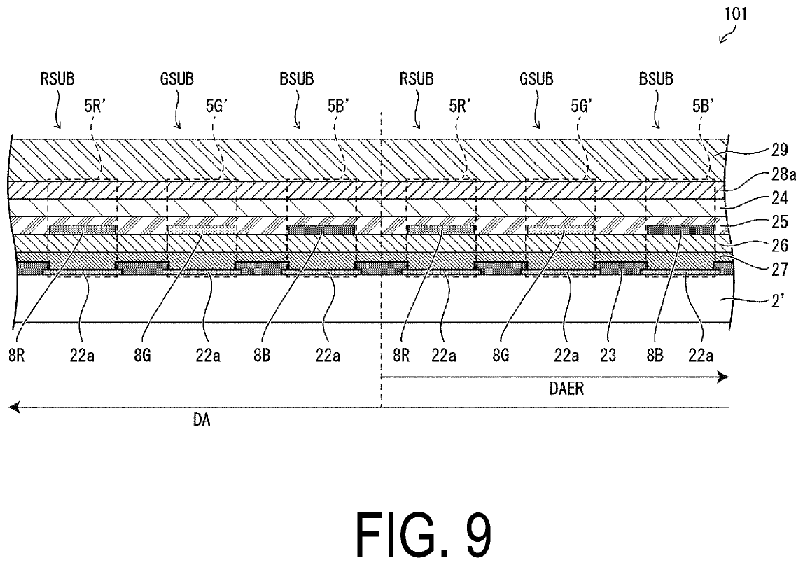

FIG. 9 is a cross-sectional view illustrating a schematic configuration of a display device 101 according to a comparative example in which the red light-emitting element 5R′, the green light-emitting element 5G′, and the blue light-emitting element 5B′ provided in an end portion area DAER of the display region DA emit light with luminance higher than the intended luminance and consequently bright lines appear.

As illustrated in FIG. 9, the red subpixel RSUB provided in the display region DA including the end portion area DAER of the display region DA in the display device 101 includes the red light-emitting element 5R′ including the red light-emitting layer 8R, the green subpixel GSUB provided in the display region DA including the end portion area DAER of the display region DA in the display device 101 includes the green light-emitting element 5G′ including the green light-emitting layer 8G, and the blue subpixel BSUB provided in the display region DA including the end portion area DAER of the display region DA in the display device 101 includes the blue light-emitting element 5B′ including the blue light-emitting layer 8B.

The electron injection layer 27 and the electron transport layer 26 are provided as a charge transfer layer (electron transfer layer) which is a common layer formed over the entire surface of the display region DA between the lower electrode 22a and the red light-emitting layer 8R provided in the red light-emitting element 5R′, between the lower electrode 22a and the green light-emitting layer 8G provided in the green light-emitting element 5G′, and between the lower electrode 22a and the blue light-emitting layer 8B provided in the blue light-emitting element 5B′ of the display device 101 according to the comparative example illustrated in FIG. 9.

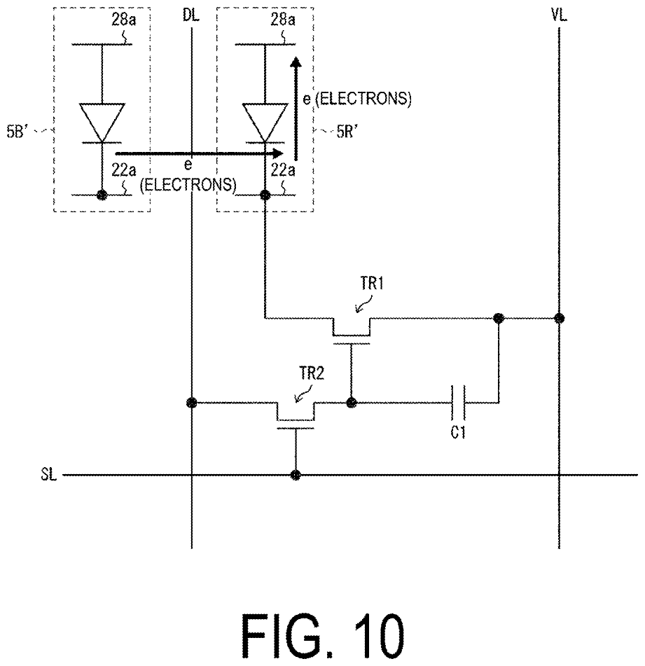

FIG. 10 is a circuit diagram for explaining a reason why a bright line appears in the end portion area DAER of the display region DA of the display device 101 according to the comparative example illustrated in FIG. 9. FIG. 10 illustrates a schematic circuit configuration of the drive circuit of the red subpixel RSUB including the red light-emitting element 5R′ provided in the end portion area DAER of the display region DA in the display device 101 according to the comparative example illustrated in FIG. 9, and the blue light-emitting element 5B′ disposed adjacent to the red light-emitting element 5R′. Since the circuit configuration illustrated in FIG. 10 is described in the first embodiment, the description thereof is omitted here.

In the display device 101 according to the comparative example illustrated in FIG. 9, in which the electron injection layer 27 and the electron transport layer 26 are provided as a charge transfer layer (electron transfer layer) which is a common layer formed over the entire surface of the display region DA, a bright line appears in the end portion area DAER of the display region DA. The inventors of the disclosure consider that one of the reasons for the occurrence of the above-mentioned bright line is as follows. As illustrated in FIG. 9 and FIG. 10, the electrons e having transferred to the end portion area DAER of the display region DA through the electron injection layer 27 and electron transport layer 26 as the charge transfer layer (electron transfer layer) are unable to go out of the end portion area DAER of the display region DA and are accumulated in the end portion area DAER thereof; then, in the light-emitting element provided in the end portion area DAER of the display region DA, the electrons e accumulated as discussed above transfer toward the upper electrode 28a, and light is emitted with luminance higher than the intended luminance. In the display device 101 according to the comparative example, a case has been described as an example in which the electron injection layer 27 and the electron transport layer 26 are provided as the charge transfer layer (electron transfer layer) which is a common layer formed over the entire surface of the display region DA. However, without being limited thereto, in a case where only one of the electron injection layer 27 and the electron transport layer 26 is provided, a bright line also appears similarly in the end portion area DAER of the display region DA.

### Third Embodiment

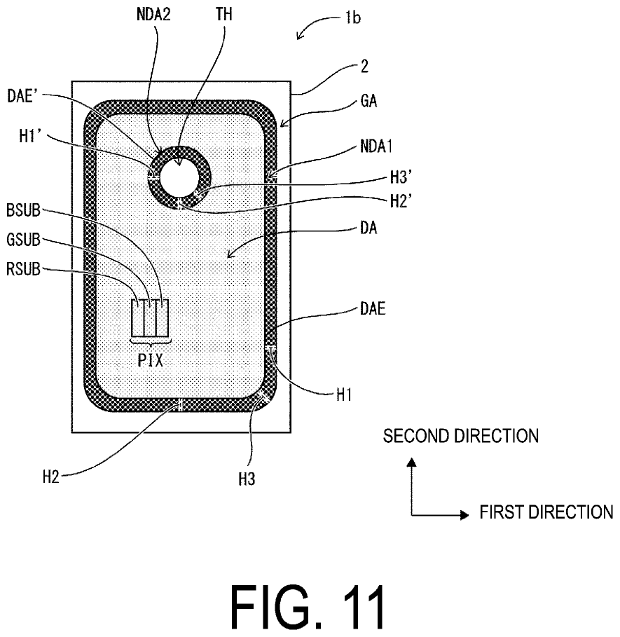

Next, with reference to FIG. 11, a third embodiment of the disclosure will be described. The third embodiment is different from the above-described first and second embodiments in that an imaging region TH configured to transmit image light is further provided inside a display region DA in a display device 1b of the present embodiment, and a first non-display region NDA1 provided to surround the outer perimeter of the display region DA and a second non-display region NDA2 provided to surround the imaging region TH are included. The others are as described in the first and second embodiments. For convenience of description, members having the same functions as the members illustrated in the diagrams in the first and second embodiments are denoted by the same reference signs, and descriptions thereof will be omitted.

FIG. 11 is a plan view illustrating a schematic configuration of the display device 1b according to the third embodiment.

As illustrated in FIG. 11, the imaging region TH configured to transmit image light is further provided inside the display region DA in the display device 1b, and the first non-display region NDA1 provided to surround the outer perimeter of the display region DA and the second non-display region NDA2 provided to surround the imaging region TH are included. The imaging region TH configured to transmit image light may be a through hole passing through from the front face to the back face of the display device 1b, or may be a region formed of only a transparent material to transmit the image light. The image light is light reflected from a subject and necessary for imaging by an imaging element (not illustrated) arranged to overlap the imaging region TH of the display device 1b in a plan view and disposed at the back face side of the display device 1b.

Each of the first non-display region NDA1 and the second non-display region NDA2 of the display device 1b may have the same configuration as the non-display region NDA1 described in the above first embodiment or may have the same configuration as the non-display region NDA1 described in the above second embodiment.

In the present embodiment, a case will be described as an example in which the imaging region TH is formed in a circular shape and the second non-display region NDA2 is also formed in a circular shape, but the shapes thereof are not limited thereto. For example, the imaging region TH may be formed in a rectangular shape and the second non-display region NDA2 may also be formed in a rectangular shape.

As illustrated in FIG. 11, since the second non-display region NDA2 is a region where no display is performed, it is preferable that the non-display region NDA2 be provided to have a width not wider than necessary. Accordingly, when the shape of a pixel PIX is rectangular as in the present embodiment, it is preferable that the second non-display region NDA2 be formed having a width equal to or less than the length of a diagonal line of the pixel PIX. In the present embodiment, a case will be described as an example in which widths H1′, H2′, and H3′ of the second non-display region NDA2 are each formed to take a width in a first direction of the pixel PIX in order to make the widths H1′, H2′, and H3′ of the second non-display region NDA2 equal to or less than the length of the diagonal line of the pixel PIX. However, the disclosure is not limited thereto, and the widths H1′, H2′, and H3′ of the second non-display region NDA2 may be each formed to take a width in a second direction of the pixel PIX or a width equal to the length of the diagonal line of the pixel PIX. For example, the widths H1′, H2′, and H3′ of the second non-display region NDA2 may be formed to be 50 μm or less, or are preferably formed to be 5 μm or more and 50 μm or less. By setting the widths of the second non-display region NDA2 to be in the above-described range, it is possible to achieve the display device 1b capable of obtaining a wider display region DA for the display device 1b and configured to suppress a situation in which the light-emitting elements provided in an end portion DAE′ area of the display region DA emit light with luminance higher than the intended luminance and consequently bright lines appear.

### Supplement

### First Aspect

A display device including:
a substrate;
a display region located on the substrate and provided with a plurality of pixels each including a plurality of subpixels;
a non-display region located on the substrate, including a plurality of dummy subpixels provided along an end portion of the display region, and continued from the display region;
a plurality of lower electrodes provided in each of the display region and the non-display region;
a charge transfer layer which is one layer provided in the display region and the non-display region; and
an upper electrode provided in the display region and the non-display region, wherein
the plurality of subpixels provided in the display region each include a light-emitting element including the lower electrode, the charge transfer layer, a light-emitting layer, and the upper electrode in that order from the substrate side, and
the plurality of dummy subpixels provided in the non-display region each include a non-emitting charge transfer element including the lower electrode, the charge transfer layer, and the upper electrode in that order from the substrate side.

### Second Aspect

The display device according to the first aspect, wherein the charge transfer layer provided in the display region and the charge transfer layer provided in the non-display region are formed of the same material.

### Third Aspect

The display device according to the first or second aspect, wherein a width of the non-display region is equal to or less than a length of a diagonal line of the pixel.

### Fourth Aspect

The display device according to the first or second aspect, wherein a width of the non-display region is formed to be 50 μm or less.

### Fifth Aspect

The display device according to any one of the first to fourth aspects, wherein
the lower electrode is an anode,
the upper electrode is a cathode, and
the charge transfer layer is at least one of a hole injection layer and a hole transport layer.

### Sixth Aspect

The display device according to the fifth aspect, wherein at least one of an electron injection layer and an electron transport layer is further provided between the light-emitting layer and the upper electrode in the display region and between the charge transfer layer and the upper electrode in the non-display region.

### Seventh Aspect

The display device according to any one of the first to fourth aspects, wherein
the lower electrode is a cathode,
the upper electrode is an anode, and
the charge transfer layer is at least one of an electron injection layer and an electron transport layer.

### Eighth Aspect

The display device according to the seventh aspect, wherein at least one of a hole injection layer and a hole transport layer is further provided between the light-emitting layer and the upper electrode in the display region and between the charge transfer layer and the upper electrode in the non-display region.

### Ninth Aspect

The display device according to any one of the first to eighth aspects, wherein
the non-display region includes a first non-display region and a second non-display region,
an imaging region configured to transmit image light is further provided inside the display region,
the first non-display region is provided to surround an outer perimeter of the display region, and
the second non-display region is provided to surround the imaging region.

### Tenth Aspect

The display device according to any one of the first to ninth aspects, wherein
the plurality of subpixels included in the pixel include a first subpixel including a first light-emitting element provided with a first light-emitting layer configured to emit light of a first color as the light-emitting layer, a second subpixel including a second light-emitting element provided with a second light-emitting layer configured to emit light of a second color different from the first color as the light-emitting layer, and a third subpixel including a third light-emitting element provided with a third light-emitting layer configured to emit light of a third color different from the first color and the second color as the light-emitting layer, and
the plurality of dummy subpixels include at least one of a first dummy subpixel formed in the same shape as the first subpixel, a second dummy subpixel formed in the same shape as the second subpixel, or a third dummy subpixel formed in the same shape as the third subpixel.

### Eleventh Aspect

The display device according to any one of the first to tenth aspects, wherein
the substrate includes a subpixel circuit provided corresponding to each subpixel of the plurality of subpixels and the plurality of dummy subpixels, and
the subpixel circuit includes a selecting transistor provided with an electrode electrically connected to a scanning signal line, an electrode electrically connected to a data signal line, and an electrode electrically connected to the light-emitting element or the non-emitting charge transfer element via a drive transistor.

### Twelfth Aspect

The display device according to the eleventh aspect, wherein a voltage in a range from 2 V to 8 V is applied to the data signal line of the subpixel circuit including the selecting transistor provided with an electrode electrically connected to the non-emitting charge transfer element via the drive transistor.

### Thirteenth Aspect

The display device according to the eleventh or twelfth aspect, wherein a voltage of 2 V is applied to the data signal line of the subpixel circuit including the selecting transistor provided with the electrode electrically connected to the non-emitting charge transfer element via the drive transistor.

### Fourteenth Aspect

The display device according to any one of the first to thirteenth aspects, wherein the non-display region is provided to surround the display region.

### Fifteenth Aspect

A method for manufacturing a display device, the method including:
forming a plurality of lower electrodes in each of a display region located on a substrate and a non-display region located on the substrate and continued from the display region;
forming an upper electrode in the display region and the non-display region after the forming a plurality of lower electrodes;
forming a light-emitting layer only in the display region between the forming a plurality of lower electrodes and the forming an upper electrode; and
forming a charge transfer layer made of one layer in the display region and the non-display region between the forming a plurality of lower electrodes and the forming a light-emitting layer.

### Appendix

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

### INDUSTRIAL APPLICABILITY

The disclosure can be utilized for a display device and a method for manufacturing the display device.

1. A display device comprising:
a substrate;
a display region located on the substrate and provided with a plurality of pixels each including a plurality of subpixels;
a non-display region located on the substrate, including a plurality of dummy subpixels provided along an end portion of the display region, and continued from the display region;
a plurality of lower electrodes provided in each of the display region and the non-display region;
a charge transfer layer which is one layer provided in the display region and the non-display region; and
an upper electrode provided in the display region and the non-display region, wherein
the plurality of subpixels provided in the display region each include a light-emitting element including the lower electrode, the charge transfer layer, a light-emitting layer, and the upper electrode in that order from the substrate side, and
the plurality of dummy subpixels provided in the non-display region each include a non-emitting charge transfer element including the lower electrode, the charge transfer layer, and the upper electrode in that order from the substrate side.

2. The display device according to claim 1,
wherein the charge transfer layer provided in the display region and the charge transfer layer provided in the non-display region are formed of an identical material.

3. The display device according to claim 1,
wherein a width of the non-display region is equal to or less than a length of a diagonal line of the pixel.

4. The display device according to claim 1,
wherein a width of the non-display region is formed to be 50 μm or less.

5. The display device according to claim 1,
wherein the lower electrode is an anode,
the upper electrode is a cathode, and
the charge transfer layer is at least one of a hole injection layer and a hole transport layer.

6. The display device according to claim 5,
wherein at least one of an electron injection layer and an electron transport layer is further provided between the light-emitting layer and the upper electrode in the display region and between the charge transfer layer and the upper electrode in the non-display region.

7. The display device according to claim 1,
wherein the lower electrode is a cathode,
the upper electrode is an anode, and
the charge transfer layer is at least one of an electron injection layer and an electron transport layer.

8. The display device according to claim 7,
wherein at least one of a hole injection layer and a hole transport layer is further provided between the light-emitting layer and the upper electrode in the display region and between the charge transfer layer and the upper electrode in the non-display region.

9. The display device according to claim 1,
wherein the non-display region includes a first non-display region and a second non-display region,
an imaging region configured to transmit image light is further provided inside the display region,
the first non-display region is provided to surround an outer perimeter of the display region, and
the second non-display region is provided to surround the imaging region.

10. The display device according to claim 1,
wherein the plurality of subpixels included in the pixel include a first subpixel including a first light-emitting element provided with a first light-emitting layer configured to emit light of a first color as the light-emitting layer, a second subpixel including a second light-emitting element provided with a second light-emitting layer configured to emit light of a second color different from the first color as the light-emitting layer, and a third subpixel including a third light-emitting element provided with a third light-emitting layer configured to emit light of a third color different from the first color and the second color as the light-emitting layer, and
the plurality of dummy subpixels include at least one of a first dummy subpixel formed in a shape identical to the shape of the first subpixel, a second dummy subpixel formed in a shape identical to the shape of the second subpixel, or a third dummy subpixel formed in a shape identical to the shape of the third subpixel.

11. The display device according to claim 1,
wherein the substrate includes a subpixel circuit provided corresponding to each subpixel of the plurality of subpixels and the plurality of dummy subpixels, and
the subpixel circuit includes a selecting transistor provided with an electrode electrically connected to a scanning signal line, an electrode electrically connected to a data signal line, and an electrode electrically connected to the light-emitting element or the non-emitting charge transfer element via a drive transistor.

12. The display device according to claim 11,
wherein a voltage in a range from 2 V to 8 V is applied to the data signal line of the subpixel circuit including the selecting transistor provided with an electrode electrically connected to the non-emitting charge transfer element via the drive transistor.

13. The display device according to claim 11,
wherein a voltage of 2 V is applied to the data signal line of the subpixel circuit including the selecting transistor provided with the electrode electrically connected to the non-emitting charge transfer element via the drive transistor.

14. The display device according to claim 1,
wherein the non-display region is provided to surround the display region.

15. A method for manufacturing a display device, the method comprising:
forming a plurality of lower electrodes in each of a display region located on a substrate and a non-display region located on the substrate and continued from the display region;
forming an upper electrode in the display region and the non-display region after the forming a plurality of lower electrodes;
forming a light-emitting layer only in the display region between the forming a plurality of lower electrodes and the forming an upper electrode; and
forming a charge transfer layer made of one layer in the display region and the non-display region between the forming a plurality of lower electrodes and the forming a light-emitting layer.
